(19) United States
(12) Patent Application Publication
(10) Pub. No.: US 2022/0234622 A1
(43) Pub. Date: Jul. 28, 2022

(54) Systems and Methods for Autonomous Vehicle Control

(71) Applicant: dRISK, Inc., Pasadena, CA (US)

(72) Inventors: Robert Chess Stetson, Pasadena, CA (US); Lorenzo Niccolini, Pasadena, CA (US); Brett Kennedy, Pasadena, CA (US); Sam O'Connor Russell, Pasadena, CA (US); Nils Goldbeck, Pasadena, CA (US); Hugh Blayney, Pasadena, CA (US); Rav Babbra, Pasadena, CA (US); Kiran Jesudasan, Pasadena, CA (US)

(73) Assignee: dRISK, Inc., Pasadena, CA (US)

(21) Appl. No.: 17/649,330

(22) Filed: Jan. 28, 2022

Related U.S. Application Data
(60) Provisional application No. 63/142,960, filed on Jan. 28, 2021.

(51) Int. Cl. B60W 60/00; B60W 30/095; G06K 9/62

(52) U.S. Cl. CPC B60W 60/0017; B60W 30/0956; B60W 2420/42; G06K 9/6256; B60W 2554/4049; B60W 30/0953

(57) ABSTRACT

Systems and methods for training AV models in accordance with embodiments of the invention are illustrated. One embodiment includes an autonomous vehicle (AV), a vehicle, a processor, and a memory, where the memory contains an AV model capable of driving the vehicle without human input, where the AV model is trained on a plurality of edge case scenarios. In a still further additional embodiment, a method for training AV models, including obtaining a data structure storing a plurality of scenarios that an AV can encounter, and distance metrics indicating the distance between each scenario, generating a list of edge case scenarios within the plurality of scenarios, identifying hazard frames within the edge case scenarios, encoding the hazard frames into one or more records interpretable by an AV model, and training the AV model using the one or more records.

### CROSS-REFERENCE TO RELATED APPLICATIONS

The current application claims the benefit of and priority under 35 U.S.C. § 119(e) to U.S. Provisional Patent Application No. 63/142,960 entitled “Systems and Methods for Training Autonomous Vehicles” filed Jan. 28, 2021. The disclosure of U.S. Provisional Patent Application No. 63/142,960 is hereby incorporated by reference in its entirety for all purposes.

### FIELD OF THE INVENTION

The present invention generally relates to the training and use of autonomous vehicle perception and control systems.

### BACKGROUND

Neural networks are a class of machine learning technique which is often utilized for “artificial intelligence” tasks. Neural networks utilize a set of artificial neurons (or “nodes”) which are linked, often in different sets of layers. Neural networks can be trained by providing a set of training data that provides a matched set of inputs and desired outputs. Neural networks can change the weights of connections between its nodes. A successfully trained neural network is capable of outputting a desired output based on an input sufficiently similar to the training data.

Autonomous vehicles (AVs) are vehicles (e.g. cars, trucks, boats, trains, etc.) that are capable of sensing their environment and safely navigating it with little or no human input. Autonomous cars are often referred to as “self-driving cars”, and the autonomous navigation feature is often referred to as “auto pilot”. Autonomy in vehicles is often categorized in six levels according to SAE standard J3016 which roughly defines said levels as: Level 0—no automation; Level 1—hands on/shared control; Level 2—hands off; Level 3—eyes off; Level 4—mind off; and Level 5—steering wheel optional. AVs are often characterized as having perception and controls subsystems, where the perception subsystem transforms sensory input into an internal representation of actors and obstacles in the outside world which must be navigated, and the controls subsystem decides on an appropriate navigation and generates throttle, braking and steering commands that executes that navigation.

### SUMMARY OF THE INVENTION

Systems and methods for training AV models in accordance with embodiments of the invention are illustrated. One embodiment includes an autonomous vehicle (AV), a vehicle, a processor, and a memory, where the memory contains an AV model capable of driving the vehicle without human input, where the AV model is trained on a plurality of edge case scenarios.

In another embodiment, the plurality of edge case scenarios are encoded in a data structure, where the data structure further encodes distance between edge case scenarios.

In a further embodiment, the distance is a scalar valued dimensional reduction of data associated with edge case scenarios.

In still another embodiment, the data structure is a risk manifold.

In a still further embodiment, the AV model is iteratively trained on the plurality of edge case scenarios, and the distribution of the training data is altered at each iterative step to expand subspaces in which the AV model underperforms.

In yet another embodiment, the AV model is a perceptual subsystem.

In a yet further embodiment, a subset of the plurality of edge case scenarios are artificially generated using a method selected from the group consisting of: applying a bandpass filter to sensor data; generating 2-D semi-opaque, semi-reflective, semi-occluding polygons into the scenario data at a position between a sensor source and an event; applying multiscale Gabor patterns to events within simulated scenarios; applying time-varying forces to moving entities within the scenarios; and applying fractal cracking to surfaces within the scenarios.

In another additional embodiment, A system for training AVs includes a processor, and a memory, containing an AV training application that directs the processor to: obtain a data structure storing a plurality of scenarios that an AV can encounter, and distance metrics indicating the distance between each scenario, generate a list of edge case scenarios within the plurality of scenarios, identify hazard frames within the edge case scenarios, encode the hazard frames into one or more records interpretable by an AV model, and train the AV model using the one or more records.

In a further additional embodiment, the data structure is a risk manifold.

In another embodiment again, the AV training application further directs the processor to evaluate the AV model on scenarios in the plurality of scenarios, and input performance metrics indicating the performance of the AV model into the data structure.

In a further embodiment again, the AV training application further directs the processor to select a distribution of edge case scenarios from the data structure based on the performance metrics for training the AV model in a second iteration of training. In still yet another embodiment, the AV model is a perceptual subsystem; and wherein a loss function used to train the AV model is modulated by an expectation of an adverse event within a given scenario.

In a still yet further embodiment, the AV model is a decision-making module; and wherein a loss function used to train the AV model is modulated by the rate of adverse events experienced by an agent on a given set of scenarios.

In still another additional embodiment, a subset of the plurality of edge case scenarios are artificially generated using a method selected from the group consisting of: applying a bandpass filter to sensor data; generating 2-D semi-opaque, semi-reflective, semi-occluding polygons into the scenario data at a position between a sensor source and an event; applying multiscale Gabor patterns to events within simulated scenarios; applying time-varying forces to moving entities within the scenarios; and applying fractal cracking to surfaces within the scenarios.

In a still further additional embodiment, a method for training AV models, including obtaining a data structure storing a plurality of scenarios that an AV can encounter, and distance metrics indicating the distance between each scenario, generating a list of edge case scenarios within the plurality of scenarios, identifying hazard frames within the edge case scenarios, encoding the hazard frames into one or more records interpretable by an AV model, and training the AV model using the one or more records.

In still another embodiment again, the data structure is a risk manifold.

In a still further embodiment again, the method further includes evaluating the AV model on scenarios in the plurality of scenarios, and inputting performance metrics indicating the performance of the AV model into the data structure.

In yet another additional embodiment, the method further includes selecting a distribution of edge case scenarios from the data structure based on the performance metrics for training the AV model in a second iteration of training.

In a yet further additional embodiment, the AV model is a perceptual subsystem; and wherein a loss function used to train the AV model is modulated by an expectation of an adverse event within a given scenario.

In yet another embodiment again, the AV model is a decision-making module; and wherein a loss function used to train the AV model is modulated by the rate of adverse events experienced by an agent on a given set of scenarios.

In a yet further embodiment again, a subset of the plurality of edge case scenarios are artificially generated using a method selected from the group consisting of: applying a bandpass filter to sensor data; generating 2-D semi-opaque, semi-reflective, semi-occluding polygons into the scenario data at a position between a sensor source and an event; applying multiscale Gabor patterns to events within simulated scenarios; applying time-varying forces to moving entities within the scenarios; and applying fractal cracking to surfaces within the scenarios.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings, which forms a part of this disclosure.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The description and claims will be more fully understood with reference to the following figures and data graphs, which are presented as exemplary embodiments of the invention and should not be construed as a complete recitation of the scope of the invention.

FIG. 1 is a system diagram for a AV training system in accordance with an embodiment of the invention.

FIG. 2 is a block diagram for a AV trainer in accordance with an embodiment of the invention.

FIG. 3 is a flow chart for an AV training process in accordance with an embodiment of the invention.

FIG. 4 is an example risk manifold in accordance with an embodiment of the invention.

FIG. 5 is another example risk manifold in accordance with an embodiment of the invention.

FIG. 6 illustrates performance on scenarios in a risk manifold at different training steps.

FIG. 7 illustrates a perception system of an AV model that has been trained in accordance with an embodiment of the invention.

FIG. 8 is a chart which shows evolution of the performance of an AV model which has been trained in accordance with an embodiment of the invention.

### DETAILED DESCRIPTION

In the field of robotics, an autonomous vehicle (AV) is any system that navigates a vehicle for any period of time without human intervention. AV can refer both to the AV model which provides the autonomous functionality, as well as the platform (i.e. vehicle) which it operates. Whereas in the history of AVs it has often been considered that the primary function of an AV is to transport its passengers and cargo from place to place while obeying traffic guidelines, the field is now starting to recognize that this is only a secondary function. A primary function of an AV is to move at speed and contend with the complexity of the real world without endangering any life or property that it carries or in its immediate vicinity. In order to meet these goals, machine learning models which provide AV functionality ideally are capable of responding to all scenarios that the AV is likely to encounter. Therefore, the training data used to train the model should be sufficiently robust as to cover all of those scenarios. In practice, there is more training data for scenarios that are common but not necessarily high risk (center cases) compared to uncommon but high risk scenarios (edge cases). Systems and methods described herein train AV models evenly over the distribution of edge cases rather than mostly center cases, with the effect of improving performance on high risk cases, without degrading real-world performance on center cases.

Fully autonomous vehicles which require no human input have not yet become a commercial reality because they are unable to handle enough safety-critical scenarios to take over from humans. Scenarios are situations in which the AV might find itself, and are typically represented via text description, as a simulation, as video and/or as sensor data recorded in the real world. Safety-critical scenarios, also referred to as edge cases, are the seemingly endless set of risky vehicle scenarios which are individually unlikely but together make up the majority of vehicular risk. Edge cases can be anything from classic scenarios such as a ball bouncing into the street predicting a following child, to more esoteric ones such as a child dressed as a green traffic light for Halloween, to more robot-specific ones such reflecting road-surfaces likely to generate false positive detection. Currently even the most advanced AVs face the challenge that whilst acting sensibly and successfully in the majority of cases they encounter most of the time (center cases), they fail dramatically when it comes to dealing with edge cases.

The current state of the art AV models are trained to handle large amounts of low-risk scenarios they encounter during trial deployment and perhaps a handful of edge cases recorded or conceived by their developers, but are unable to handle the large numbers of edge cases they will encounter during real-life deployment. As the substantial economic benefits of AVs can only be achieved when the driver can be completely removed from the vehicle, a fully driverless car which can handle large numbers of edge cases remains a primary goal for the industry. However, merely adding more edge cases is not necessarily sufficient. The type, number, and matter in which the edge cases are presented can greatly impact the performance of the trained AV model.

Systems and methods described herein enable an AV to perform exceptionally at avoiding collisions while maintaining adequate performance on more common driving scenarios. This is accomplished by training the autonomous vehicle perceptions and controls on a large number of edge cases. Most AV development paradigms spend most of their time training AVs on the scenarios they will see most of the time (center cases), and then suffer poor performance on edge cases, resulting in AVs exhibiting risky behavior such as missing hazards and incorrect evasive maneuvers. But by training an AV primarily on the huge number of edge cases that they will see only a small fraction of the time, it is possible to still achieve adequate or even superior performance on the “center cases” they'll encounter most of the time, resulting in a safer and more performant AV over all cases.

An important substrate for this invention is a source of edge case data which can provide edge cases in the right distribution for training. Overtraining on edge cases of one kind can bias the AV against edge cases of another kind. In various embodiments, a central feature of this substrate is a similarity metric, such that scenarios that are similar to each other in terms of the trajectories and sensory signatures of actors in the scenario are likewise near to each other in the similarity metric. In many embodiments, on this substrate, edge cases are defined as the scenarios which tend to be most distant from the others overall, and center cases are scenarios that tend to be more similar to all other scenarios. After populating this substrate with driving data, the distance metric can be used to ensure the appropriate distribution of edge cases are provided to retrain the AV to perform well across edge cases, which further results in nominal performance on center cases.

As will be discussed below, training on edge-case scenarios in accordance with methods described herein increases performance on central scenarios without direct training on the central scenarios. In many embodiments, this significantly increases the computational efficiency of training AVs. However, it is not a trivial task to identify, select, and provide edge case scenarios for training. Systems and methods described herein utilize a “risk manifold” which is a specific type of data structure that contains scenarios, distance metrics that identify differences between said scenarios, and a risk metric for each scenario reflecting a level of danger of the respective scenario. Manifolds and their construction are discussed in U.S. Patent Publication 2020/0081445 titled “Systems and Methods for Graph-Based AI Training”, filed Sep. 10, 2019, the disclosure of which is incorporated by reference in its entirety.

In many embodiments, risk manifolds as described herein encode similarities and differences between edge cases (and between edge and center cases). In many embodiments, risk manifolds embed heterogeneous scenario data into a uniform manifold of scenarios. Using a principled method for establishing similarity between the physical, semantic and risk properties of scenario data enables un-biasing of center cases over edge cases and an un-biasing of any one edge case over another. This can further enable sampling and traversal of the map of edge cases in such a way as to achieve optimal training. As can readily be appreciated, while the below discusses in the context of risk manifolds, any data structure (or set of data structures) which contains identified edge case scenarios and distance metrics identifying the distances between said scenarios. Examples of other types of data structures can include (but is not limited to) hierarchical divisive clustering trees that divide up the scenario space based on a set of annotations that describe each scenario; and a dimensionally reduced embedding of the scenarios based on a set of annotations that describe each scenario.

Edge cases used for training can be organized such that no one kind of edge case dominates training, and none are left out. AV development paradigms that focus on contending with certain classes of edge cases, e.g. construction zones, might result in AVs which are even more predisposed to fail at others, such as pedestrians emerging from behind trucks on the highway. On the other hand, an AV trained on an even distribution of scenarios across the entire map of risk events will perform uniformly well on all edge cases. Therefore, a training resource that determines what constitutes an even and uniform distribution over all edge cases is critical. By way of example, such a training resource would identify a strong similarity between two road work scenarios with crew sizes of 10 or 11, while differentiating scenarios with one semi-occluded pedestrian from those with two.

In numerous embodiments, risk manifolds can be used separately or in conjunction with merged perceptual and decision-making systems (which are conventionally treated as separate) in order to promote earlier detection of risk events. Loss functions that are risk-sensitive can further be used to enhance the quality of trained models. Systems for training AVs are discussed below.

### AV Training Systems

AV training systems can train AV models using scenario data. In many embodiments, AV training systems are implemented on any of a variety of distributed and/or remote (cloud) computing platforms. However, AV training systems can be implemented on local architectures as well. AV training systems can further include connections to third party systems, and in numerous embodiments, retrieve scenario data that can be incorporated into a risk manifold.

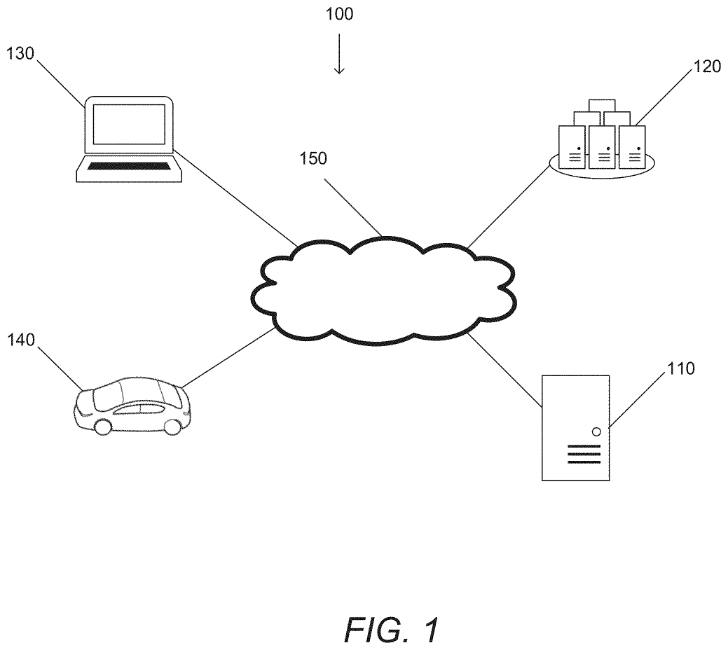

Turning now to FIG. 1, an AV training system in accordance with an embodiment of the invention is illustrated. System 100 includes an AV trainer 110. AV trainers can generate risk manifolds from graph databases and use them to train AV control models (also generally referred to herein as AVs). System 100 further includes data severs 120. Data servers can provide data desired by a user, which in turn can be encoded into a risk manifold. In numerous embodiments, data servers are third party servers which contain scenario data. Scenario data can include (but is not limited to) text descriptions, simulations, video, and/or any other encoding of an AV scenario in accordance with an embodiment of the invention. In some embodiments, third party severs include graph databases that contain the scenario data.

System 100 further includes at least one display device 130. Display devices are devices which enable humans to interact with the system, such as, but not limited to, personal computers, tablets, smartphones, smart televisions, and/or any other computing device capable of enabling a human to interface with a computer system as appropriate to the requirements of specific applications of embodiments of the invention. In numerous embodiments, the display device and AV trainer are implemented using the same hardware.

System 100 includes AV platforms 140. AV platforms can be any number of vehicles which utilize AV models to control their autonomous operation. While the majority of the discussion herein is noted with respect to cars and trucks, as can readily be appreciated, example AV platforms can include (but are not limited to) cars, trucks, robotic systems, virtual assistants, and/or any other program or device that can incorporate an AI or ML system as appropriate to the requirements of specific applications of embodiments of the invention.

Components of system 100 are connected via a network 150. In numerous embodiments, the network is a composite network made of multiple different types of network. In many embodiments, the network includes wired networks and/or wireless networks. Different network components include, but are not limited to, the Internet, intranets, local area networks, wide area networks, peer-to-peer networks, and/or any other type of network as appropriate to the requirements of specific applications of embodiments of the invention. In various embodiments, AV models can be updated on AV platforms via a deployed update over the network. While an AV training system is described with respect to FIG. 1, any number of different systems can be architected in accordance with embodiments of the invention. For example, many embodiments may be implemented using a single computing platform. In a variety of embodiments, AV platforms are not connected via a network, and instead can be loaded with AV models prior to real-world deployment. As one of ordinary skill in the art can appreciate, many different configurations of AV training systems are possible in accordance with embodiments of the invention.

### AV Trainers

AV trainers are devices that can train AV models using risk manifolds. In numerous embodiments, AV trainers provide tool suites for manipulating, rendering, and utilizing risk manifolds. In a variety of embodiments, AV trainers are capable of generating risk manifolds from graph databases. In many embodiments, AV trainers include many or all of the capabilities of graph interface devices as described in U.S. Patent Publication 2020/0081445. Many tools that can be provided by many embodiments of AV trainers are discussed in below sections.

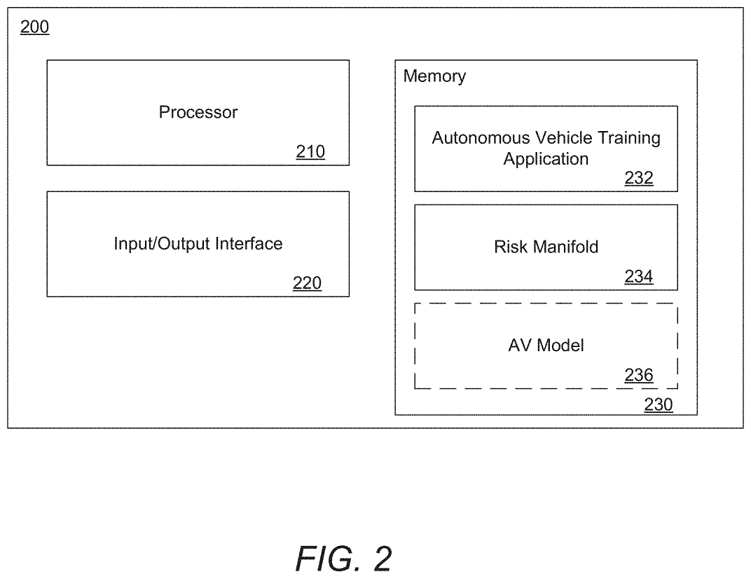

Turning now to FIG. 2, a conceptual block diagram of an AV trainer in accordance with an embodiment of the invention is illustrated. AV trainer 200 includes a processor 210. Processors can be any processing unit capable of performing logic calculations such as, but not limited to, central processing units (CPUs), graphics processing units (GPUs), application-specific integrated circuits (ASICs), field-programmable gate arrays (FPGAs), or any other processing device as appropriate to the requirements of specific applications of embodiments of the invention.

AV trainer 200 further includes an I/O interface 220. I/O interfaces can enable communication between the graph interface device, other components of a AV training system, and/or any other device capable of connection as appropriate to the requirements of specific applications of embodiments of the invention. AV trainer 200 further includes a memory 230. Memories can be any type of memory, such as volatile memory, non-volatile memory, or any mix thereof. In many embodiments, different memories are utilized within the same device. In a variety of embodiments, portions of the memory may be implemented externally to the device.

Memory 230 includes a, AV training application 230. In a variety of embodiments, AV training applications direct the processor to carry out AV training processes as described herein. Memory 230 further includes a risk manifold 234. In many embodiments memory 230 further includes at least one AV model 236 to be trained using the risk manifold.

While a specific implementation of an AV trainer is illustrated with respect to FIG. 2, any number of different architectures can be utilized as appropriate to the requirements of specific applications of embodiments of the invention. For example, different interfaces, numbers of processors, types of components, and/or additional or fewer stored data in memory can be utilized as appropriate to the requirements of specific applications of embodiments of the invention. AV training processes which can be carried out by AV training systems are discussed below.

### AV Training Processes

AV training processes as described herein train AV models using risk manifolds by primarily sampling high-risk, low-probability scenarios without losing performance on low-risk, high-probability scenarios. In numerous embodiments, sampled scenarios are selected to balance training on different classes of scenario in order to avoid performance degradation due to over-training. In many embodiments, AV training processes further include generating artificial scenarios based on real-world scenarios in order to fill out the manifold. Artificial scenarios can be generated in a variety of ways including (but not limited to): applying a bandpass filter to sensor data; generating 2-Dimensional semi-opaque, semi-reflective, semi-occluding polygons into the scenario data at a position between the sensor source and an event; applying multiscale Gabor patterns to events within the simulated scenarios; applying time-varying forces to moving entities within the scenarios; and applying fractal cracking to surfaces within the scenarios. As can readily be appreciated, there are many different ways to create artificial scenarios without departing from the scope or spirit of the invention and the aforementioned list is not exhaustive. For example, in some embodiments, the distribution of training data provided to the AV model is iteratively altered to expand subspaces in which the AV model is currently underperforming while using an unchanged version of the risk manifold as a reference.

Both artificial and real scenarios can be combined in a single risk manifold and a similarity metric between artificial and real scenarios can be established over the physical and/or semantic attributes of artificial and real scenarios. In many embodiments, the similarity metric can be determined by a loss function which compares features from the artificial and real scenarios. These features can include (but are not limited to), annotations, and features output by a neural network trained to localize vehicles within the scenario, spatial features extracted from deep convolutional neural networks, and/or estimated trajectories of vehicles in the vicinity of the AV. Artificial scenarios can be evaluated by using the inverse of a performance metric which provides a quantitative measure of the performance of sensors with respect to ground-truth data. In various embodiments, similar evaluations can be performed on real-world data. Sensors in question may be video cameras, LIDAR systems, and/or any other type of machine vision sensor as appropriate to the requirements of specific applications of embodiments of the invention. In various embodiments, the sensor outputs the rectangular regions in pixel space which contain and object and assign the object a category label. Labels can be (but are not limited to) vehicle type, hazard, pedestrian, sign, and/or any other label as appropriate to the scenario. The sensors can be further defined as a mean average precision metric computing using ground truth and the aforementioned rectangular regions and category labels. In some embodiments, the mean average precision metric uses a receiver operating characteristic (ROC) curve for the sensor, for a given intersection over the union (IoU) threshold for the sensor's rectangular outputs and the ground truth labels precision=ROC_{IoU} (recall). The ROC curve can be interpolated at N recall values to generate the mean average precision metric: mAP@IoU=1/N*ΣᵢROC(recallᵢ).

In various embodiments, the AV model is a supervised machine learning model such as (but not limited to) a neural network. The model can be provided scenarios as training data sampled by an automated teacher which draws training examples from clusters of scenarios within the manifold. In various embodiments, the examples are drawn according to a weighting:

$${w}_{i} = \frac{{l}_{i}}{{sum}_{i = 0}^{N} {l}_{i}}$$

where ‘i’ refers to a cluster of events unseen by the AV model during training within the manifold of scenarios on which AV model is evaluated, and ‘I’ is the average loss over said cluster. Each scenario can be labeled with any number of different dimensions, and the similarity between scenarios in the manifold can be used as a distance metric for clustering.

Further, as noted above, the AV model may include a perceptual subsystem of the AV platform. The loss function used for training can be modulated by the expectation of an adverse event within the scenario:

$${L}_{s}^{′} = {L}_{s} ⋆ {\sum }_{i} [ {E}_{s} [ {e}_{s} , i ] ]$$

where s is the scenario and eₛ,I is an event within the scenario. In various embodiments, the contribution to the overall loss from a given detection is modulated by the expectation of an adverse outcome expected from the detection's underlying event: L_{s,e}′=L_{s,e}*Eₛ[eₛ,i]. In many embodiments, the contribution to the overall loss from a given detection is modulated by time until an adverse outcome expected from the detection's underlying event: L_{s,e}′=L_{s,e}*f(t−t₀)*Eₛ[eₛ,i], where t_0 is the earliest time that a detection appears in the sensor data and f(t)={1: t<0; >1: t=0; lim(f(t))->1: t->inf}, thus prioritizing early detections of high-risk events.

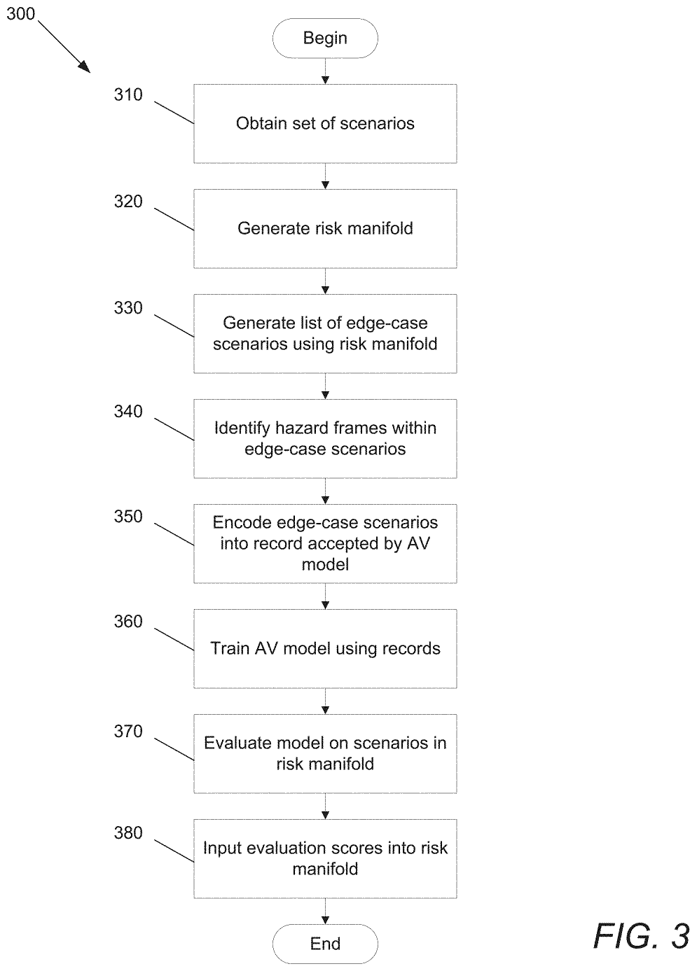

Turning now to FIG. 3, an AV training process in accordance with an embodiment of the invention is illustrated. Process 300 includes obtaining (310) a set of scenarios. In various embodiments, the set of scenarios is augmented with artificial scenarios as described above. In some embodiments, the set of scenarios is stored in a graph database. A risk manifold is generated (320) from the set of scenarios and a list of edge-case scenarios in the manifold is generated (330). Hazard frames (i.e. portions of the scenario which are identified as containing an impending hazard to the AV) are identified (340) within the edge-case scenarios. In many instances, existing AV models may require a certain format of input for training data. The edge-case scenarios are encoded (350) into a record acceptable as input to the AV model, and the AV model is trained (360) using those records. Subsequent to or during training, the AV model can be evaluated (370) on other scenarios in the risk manifold (and/or in scenarios in a separate evaluation risk manifold). The evaluations are input (380) into the manifold in order to further direct scenario selection.

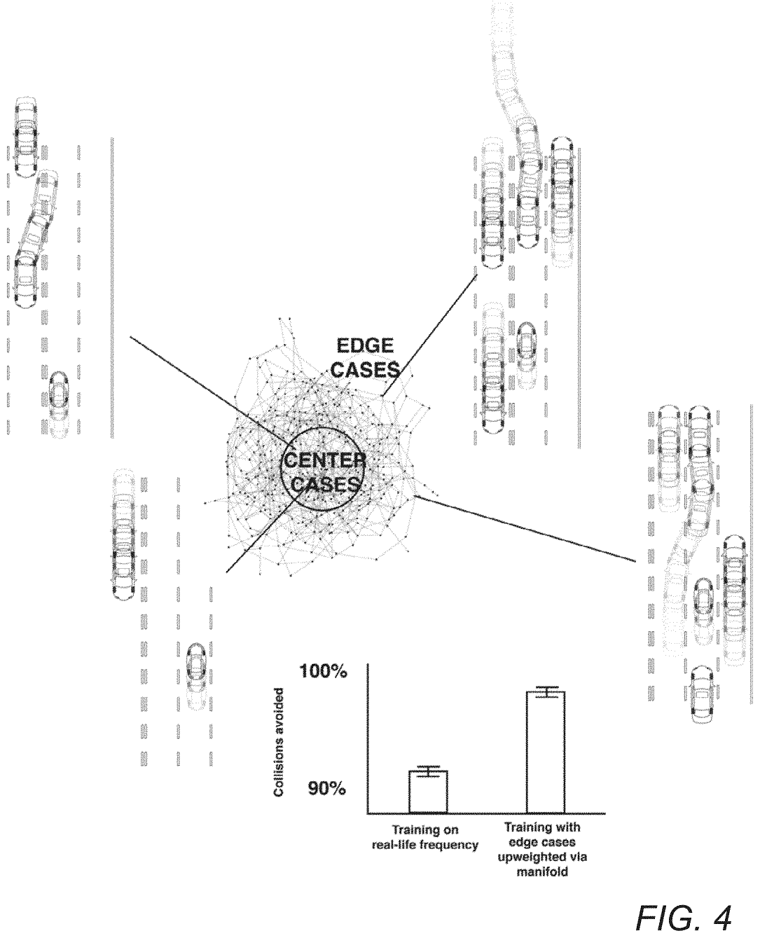

Turning now to FIG. 4, an example risk manifold in accordance with an embodiment of the invention is illustrated. Risk manifolds like those illustrated in FIG. 4 can be used to train AV models using processes like process 300. As can be seen in the chart, the AV model trained primarily to navigate edge cases also successfully navigates center cases, whereas the converse is not the case. In the illustrated embodiment, training to navigate center cases does not confer the ability to navigate all cases (including edge cases, p<10⁻¹⁰) Scenarios are shown that correspond either to center cases represented as being near the center of the manifold and corresponding to be frequent occurrences in the underlying data; and edge cases, represented as being near the edge of the manifold and corresponding to infrequent and high-risk occurrences within the underlying data. An AV trained evenly over this manifold enjoys improved performance in avoiding collisions.

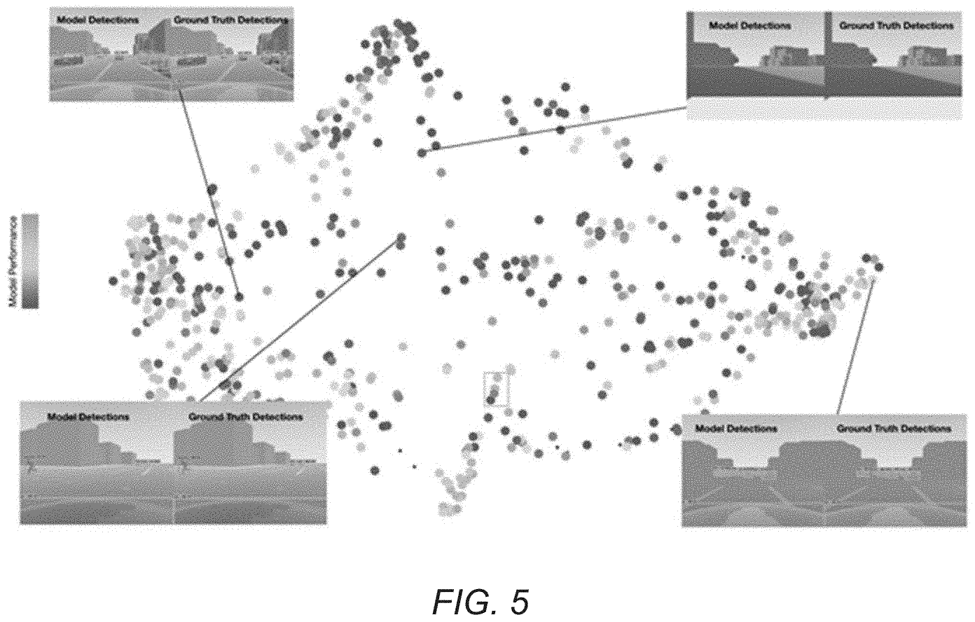

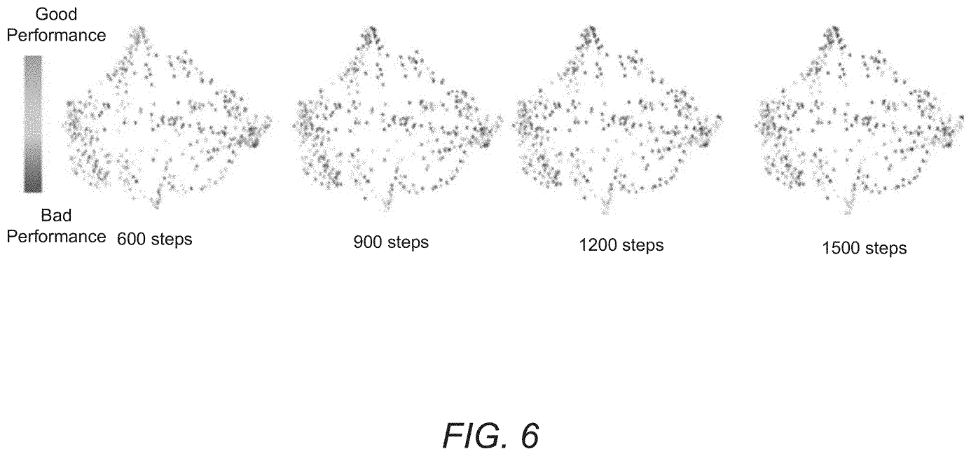

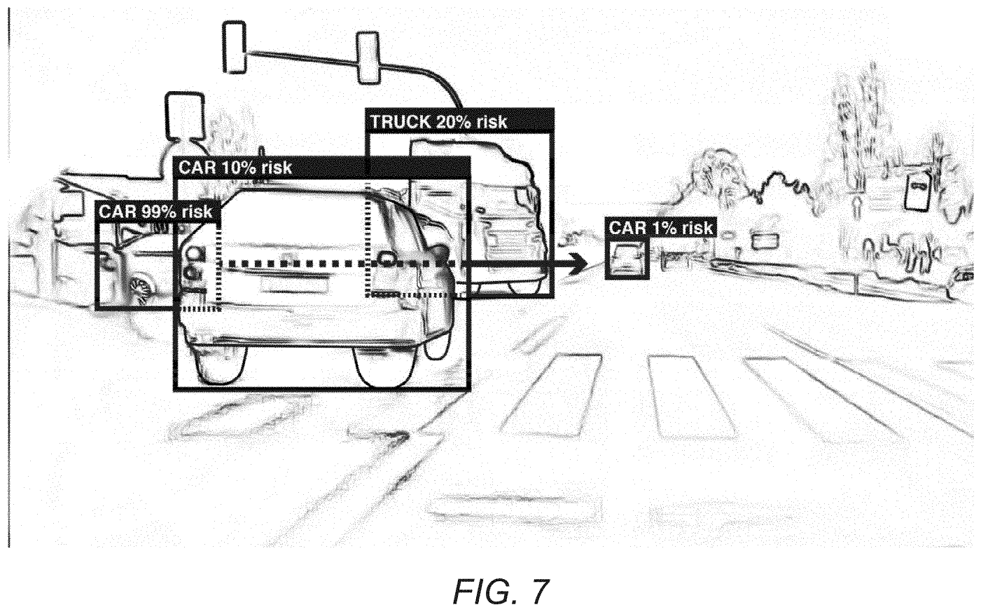

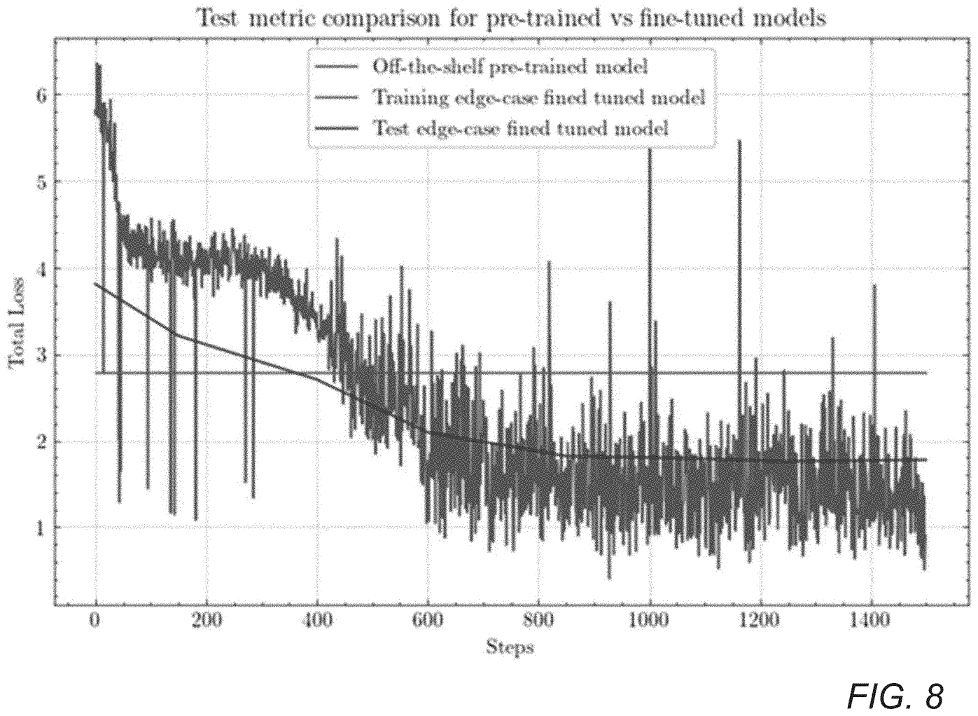

Turning now to FIG. 5, a risk manifold in accordance with an embodiment of the invention is illustrated. Insets show sensor images from corresponding scenarios, annotated with ground truth and model detections. Performance on the risk manifold after various numbers of training steps are illustrated in FIG. 6. As can be scene, performance on scenarios across the manifold radically improve (including center cases) after training on edge cases. FIG. 7 illustrates the perception system of an AV model that has been trained using methods described herein. In the image, the highest risk vehicle is mostly occluded, but is nevertheless recognized by the perception system, and labeled as having a high (99%) risk. In various embodiments, an AV perception system may be trained to identify high-risk features of the visual scene. In the illustrated video image (enhanced for clarity to the reader), an object detection algorithm trained on videos from high-risk events assigns a high-risk value to the small visible part of a car that will end up running the red light and entering the intersection at high speed. In contrast, other more visible vehicles are identified as low-risk. Different objects viewed by the AV's sensors are assigned risk which can be used to feed a decision system. FIG. 8 reflects performance of an AV model which has been trained using processes described herein.

Although the present invention has been described in certain specific aspects, many additional modifications and variations would be apparent to those skilled in the art. In particular, any of the various processes described above can be performed in alternative sequences in order to achieve similar results in a manner that is more appropriate to the requirements of a specific application. Further, other data structures besides manifolds can be used that enable training on edge cases without departing from the scope or spirit of the invention. It is therefore to be understood that the present invention can be practiced otherwise than specifically described without departing from the scope and spirit of the present invention. Thus, embodiments of the present invention should be considered in all respects as illustrative and not restrictive.

What is claimed is:

1. An autonomous vehicle (AV), comprising:
a vehicle;
a processor; and
a memory, where the memory contains an AV model capable of driving the vehicle without human input;
where the AV model is trained on a plurality of edge case scenarios.

2. The AV of claim 1, wherein the plurality of edge case scenarios are encoded in a data structure, where the data structure further encodes a distance metric between edge case scenarios.

3. The AV of claim 2, wherein the distance is a scalar valued dimensional reduction of data associated with edge case scenarios.

4. The AV of claim 2, wherein the data structure is a risk manifold.

5. The AV of claim 4, wherein the AV model is iteratively trained on the plurality of edge case scenarios, and the distribution of the training data is altered at each iterative step to expand subspaces in which the AV model underperforms.

6. The AV of claim 1, wherein the AV model is a perceptual subsystem.

7. The AV system of claim 1, wherein a subset of the plurality of edge case scenarios are artificially generated using a method selected from the group consisting of: applying a bandpass filter to sensor data; generating 2-D semi-opaque, semi-reflective, semi-occluding polygons into the scenario data at a position between a sensor source and an event; applying multiscale Gabor patterns to events within simulated scenarios; applying time-varying forces to moving entities within the scenarios; and applying fractal cracking to surfaces within the scenarios.

8. A system for training autonomous vehicles (AVs), comprising:
a processor; and
a memory, containing an AV training application that directs the processor to:
obtain a data structure storing a plurality of scenarios that an AV can encounter, and distance metrics indicating the distance between each scenario;
generate a list of edge case scenarios within the plurality of scenarios;
identify hazard frames within the edge case scenarios;
encode the hazard frames into one or more records interpretable by an AV model; and
train the AV model using the one or more records.

9. The system for training AVs of claim 8, wherein the data structure is a risk manifold.

10. The system for training AVs of claim 8, wherein the AV training application further directs the processor to:
evaluate the AV model on scenarios in the plurality of scenarios; and
input performance metrics indicating the performance of the AV model into the data structure.

11. The system for training AVs of claim 10, wherein the AV training application further directs the processor to select a distribution of edge case scenarios from the data structure based on the performance metrics for training the AV model in a second iteration of training.

12. The system for training AVs of claim 8, wherein the AV model is a perceptual subsystem; and wherein a loss function used to train the AV model is modulated by an expectation of an adverse event within a given scenario.

13. The system for training AVs of claim 8, wherein the AV model is a decision-making module; and wherein a loss function used to train the AV model is modulated by the rate of adverse events experienced by an agent on a given set of scenarios.

14. The system for training AVs of claim 8, wherein a subset of the plurality of edge case scenarios are artificially generated using a method selected from the group consisting of: applying a bandpass filter to sensor data; generating 2-D semi-opaque, semi-reflective, semi-occluding polygons into the scenario data at a position between a sensor source and an event; applying multiscale Gabor patterns to events within simulated scenarios; applying time-varying forces to moving entities within the scenarios;
and applying fractal cracking to surfaces within the scenarios.

15. A method for training autonomous vehicle (AV) models, comprising:
obtaining a data structure storing a plurality of scenarios that an AV can encounter, and distance metrics indicating the distance between each scenario;
generating a list of edge case scenarios within the plurality of scenarios;
identifying hazard frames within the edge case scenarios;
encoding the hazard frames into one or more records interpretable by an AV model; and
training the AV model using the one or more records.

16. The method for training AV models of claim 15, wherein the data structure is a risk manifold.

17. The method for training AV models of claim 15, further comprising:
evaluating the AV model on scenarios in the plurality of scenarios; and
inputting performance metrics indicating the performance of the AV model into the data structure.

18. The method for training AV models of claim 17, further comprising selecting a distribution of edge case scenarios from the data structure based on the performance metrics for training the AV model in a second iteration of training.

19. The method for training AV models of claim 15, wherein the AV model is a perceptual subsystem; and wherein a loss function used to train the AV model is modulated by an expectation of an adverse event within a given scenario.

20. The method for training AV models of claim 15, wherein the AV model is a decision-making module; and wherein a loss function used to train the AV model is modulated by the rate of adverse events experienced by an agent on a given set of scenarios.

21. The method for training AV models of claim 15, wherein a subset of the plurality of edge case scenarios are artificially generated using a method selected from the group consisting of: applying a bandpass filter to sensor data; generating 2-D semi-opaque, semi-reflective, semi-occluding polygons into the scenario data at a position between a sensor source and an event; applying multiscale Gabor patterns to events within simulated scenarios; applying time-varying forces to moving entities within the scenarios; and applying fractal cracking to surfaces within the scenarios.
